(19) United States
(12) Patent Application Publication
(10) Pub. No.: US 2016/0132148 A1
(43) Pub. Date: May 12, 2016

(54) ORGANIC LIGHT-EMITTING DIODE (OLED) DISPLAY

(71) Applicant: Samsung Display Co., Ltd., Yongin-city (KR)

(72) Inventors: Kwan Young Han, Seongnam-si (KR); Sang Kook Kim, Cheonan-si (KR)

(21) Appl. No.: 14/670,272

(22) Filed: Mar. 26, 2015

(30) Foreign Application Priority Data
Nov. 6, 2014 (KR) 10-2014-0153559

(51) Int. Cl. G06F 3/044; H01L 27/32; G06F 3/041

(52) U.S. Cl. CPC G06F 3/044; G06F 3/0416; H01L 27/323; H01L 27/3251; G06F 2203/04111; G06F 2203/04103

(57) ABSTRACT

An organic light-emitting diode (OLED) display is disclosed. In one aspect, the OLED display includes a display substrate including a display area configured to display an image and a peripheral area surrounding the display area. The OLED display also includes a thin film display layer formed over the display substrate in the display area and a shielding electrode formed over the entire surface of the thin film display layer. The OLED display further includes an encapsulation substrate formed over the display substrate and a touch electrode layer interposed between the encapsulation substrate and the thin film display layer.

### CROSS-REFERENCE TO RELATED APPLICATION

This application claims priority to and the benefit of Korean Patent Application No. 10-2014-0153559 filed in the Korean Intellectual Property Office on Nov. 6, 2014, the entire contents of which are incorporated herein by reference.

### BACKGROUND

1. Field

The described technology generally relates to an organic light-emitting diode (OLED) display.

2. Description of the Related Technology

Display devices such as liquid crystal displays (LCDs), organic light-emitting diode (OLED) displays, and electrophoretic displays (EPDs) include a field generating electrode and an electro-optical active layer. For example, OLED displays include an organic emission layer as the electro-optical active layer and EPDs include charged particles. The field generating electrode is connected to a switching element such as a thin film transistor to receive a data signal and the electro-optical active layer converts the received data signal to an optical signal to display images.

Recently, OLED displays have been manufactured to include touch sensors to receive input from a user. These touch sensors are used to generate touch information such as whether an object touches a screen and the touch location thereof by sensing a change in physical parameters of the touch sensor, such as pressure applied to the screen, charge, light, or the like, when a user touches a finger or a touch pen to the screen. The display can receive an image signal based on the touch information, thereby displaying an image.

The above information disclosed in this Background section is only intended to facilitate the understanding of the background of the described technology and therefore it may contain information that does not form the prior art that is already known in this country to a person of ordinary skill in the art.

### SUMMARY OF CERTAIN INVENTIVE ASPECTS

One inventive aspect is an OLED display that can minimize the undesired interference between a touch electrode layer and a thin film display layer, where the OLED display includes an in-cell touch electrode layer formed under an encapsulation substrate.

Another aspect is an OLED display including a display substrate divided into a display area displaying an image and a peripheral area formed outside the display area; a thin film display layer formed at the display area on the display substrate; a shielding electrode formed on an entire surface on the thin film display layer; an encapsulation substrate formed on the display substrate; and a touch electrode layer formed under the encapsulation substrate while facing the thin film display layer.

An insulating layer can be interposed between the shielding electrode and the touch electrode layer.

The shielding electrode can be a transparent electrode.

The shielding electrode can be formed of indium tin oxide (ITO), indium zinc oxide (IZO), indium tin zinc oxide (ITZO), or antimony tin oxide (ATO).

A touch driving integrated circuit (IC) can be formed at one side of the peripheral area of the display substrate and transmit a signal with the touch electrode layer and a display driving IC can transmit a signal to the thin film display layer.

The touch driving IC and the display driving IC can be connected to the shielding electrode.

A flexible printed circuit board (FPCB) can be formed at one side of the peripheral area of the display substrate and connected to the touch driving IC and the display driving IC and a controller can be connected to the FPCB, generate the signal transmitted to the touch driving IC and the display driving IC, and generate a voltage signal of a predetermined level.

The voltage signal of the predetermined level generated in the controller can be applied to the shielding electrode.

The voltage signal of the predetermined level applied to the shielding electrode can be a general voltage or a ground voltage.

A guide ring can be formed at the peripheral area of the display substrate and prevent static electricity from flowing into the display area.

The guide ring and the shielding electrode can be formed of the same material.

A polarization layer can be formed on the encapsulation substrate and a window can be formed on the polarization layer.

A resin layer can be interposed between the polarization layer and the window.

The resin layer can adhere to the window and can be hardened by irradiation of ultraviolet rays.

Technical objectives desired to be achieved by the described technology are not limited to the aforementioned, and other technical objectives not described above will be apparent to those skilled in the art from the following disclosure of the described technology.

Another aspect is an OLED display comprising a display substrate including a display area configured to display an image and a peripheral area surrounding the display area; a thin film display layer formed over the display substrate in the display area; a shielding electrode formed over the entire surface of the thin film display layer; an encapsulation substrate formed over the display substrate; and a touch electrode layer interposed between the encapsulation substrate and the thin film display layer.

In example embodiments, the OLED display further comprises an insulating layer interposed between the shielding electrode and the touch electrode layer. The shielding electrode can be transparent. The shielding electrode can be formed of one of the following materials: indium tin oxide (ITO), indium zinc oxide (IZO), indium tin zinc oxide (ITZO), and antimony tin oxide (ATO). The OLED display can further include a touch driving integrated circuit (IC) formed at one side of the peripheral area of the display substrate and configured to transmit a first signal to the touch electrode layer; and a display driving IC configured to transmit a second signal to the thin film display layer.

In example embodiments, the touch driving IC and the display driving IC are electrically connected to the shielding electrode. The OLED display can further comprise a flexible printed circuit board (FPCB) arranged at the one side of the peripheral area of the display substrate and electrically connected to the touch driving IC and the display driving IC; and a controller electrically connected to the FPCB and configured to: i) generate the first and second signals, ii) respectively transmit the first and second signals to the touch driving IC and the display driving IC, and iii) generate a voltage signal having a predetermined level.

In example embodiments, the controller is further configured to apply the voltage signal to the shielding electrode. The voltage signal can comprise a general voltage or a ground voltage. The OLED display can further comprise a guide ring formed over the display substrate in the peripheral area and configured to prevent static electricity from flowing into the display area. The guide ring and the shielding electrode can be formed of the same material. The OLED display can further comprise a polarization layer formed over the encapsulation substrate; and a window formed over the polarization layer. The OLED display can further comprise a resin layer interposed between the polarization layer and the window.

According to at least one embodiment, the following effects can be provided.

In one embodiment the shielding electrode is interposed between the thin film display layer and the touch electrode layer such that unnecessary signal interference can be reduced between the thin film display layer and the touch electrode layer.

Another embodiment includes the guide ring in the peripheral area on the display substrate such that influence of external static electricity flowing into the display panel can be prevented.

In addition to the above-stated effects, other features and advantages of the described technology can be determined based on the disclosure of the described technology.

### BRIEF DESCRIPTION OF THE DRAWINGS

FIG. 1 is a schematic top plan view of an OLED display according to an exemplary embodiment.

FIG. 2 is a schematic lateral view of a lateral surface of the OLED display of FIG. 1.

FIG. 3 is a schematic top plan view of an OLED display according to another exemplary embodiment.

FIG. 4 is a schematic lateral view of a lateral surface of the OLED display of FIG. 3.

FIG. 5 is a top plan view of a touch electrode layer of the OLED display shown in FIG. 1 and FIG. 3.

FIG. 6 is a partial enlarged view of the touch electrode layer shown in FIG. 5.

FIG. 7 is a cross-sectional view taken along line VII-VII of FIG. 6.

FIG. 8 is an equivalent circuit diagram of one pixel of the OLED display shown in FIG. 1 and FIG. 3.

FIG. 9 is a layout view of one pixel of the OLED display shown in FIG. 1 and FIG. 3.

FIG. 10 is a cross-sectional view taken along line X-X of FIG. 9.

### DETAILED DESCRIPTION OF CERTAIN INVENTIVE EMBODIMENTS

Hereinafter, exemplary embodiments will be described in detail with reference to the accompanying drawings. As those skilled in the art would realize, the described embodiments may be modified in various different ways, all without departing from the spirit or scope of the described technology. On the contrary, exemplary embodiments introduced herein are provided to so that this disclosure will be thorough and complete, and will fully convey how to implement the invention to those skilled in the art.

In the drawings, the thicknesses of layers, films, panels, regions, etc., may be exaggerated for the sake of clarity. It will be understood that when a layer is referred to as being “on” another layer or substrate, it can be directly on the other layer or substrate, or intervening elements may also be present. Like reference numerals designate like elements throughout the specification.

Exemplary embodiments of the described technology will now be described with reference to accompanying drawings.

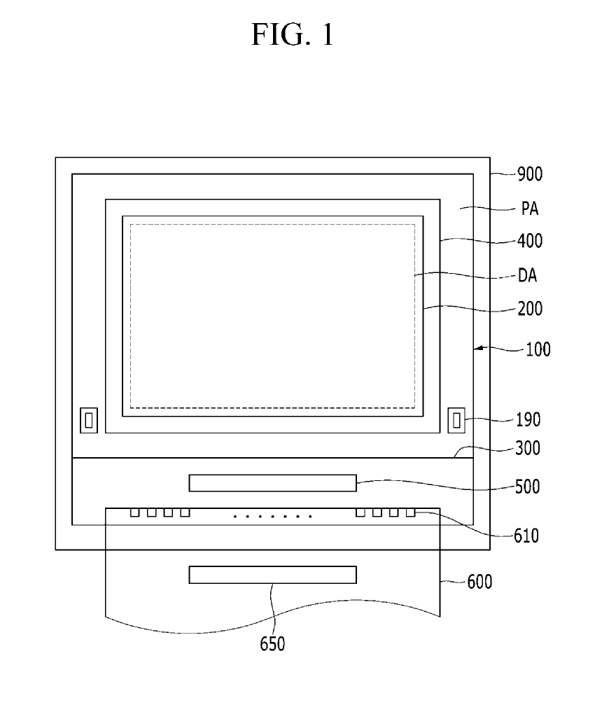

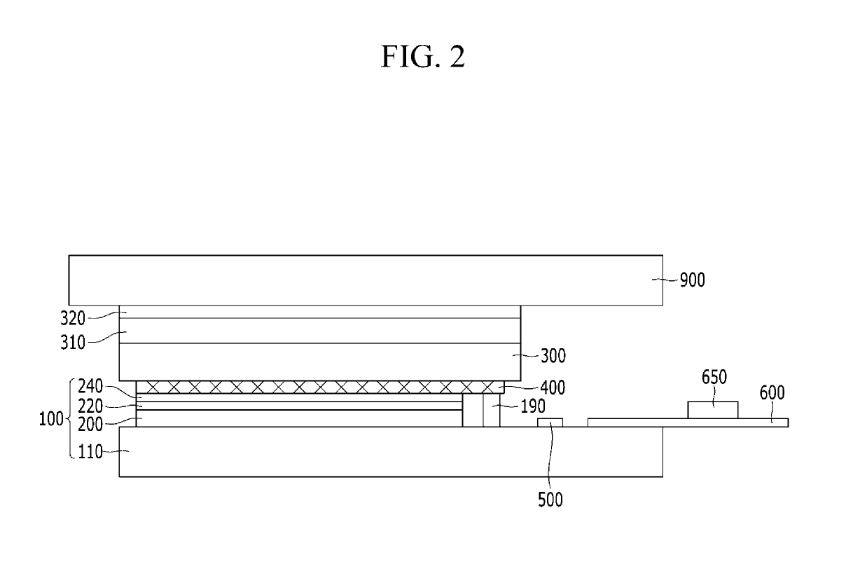

FIG. 1 is a schematic top plan view of an OLED display according to an exemplary embodiment. FIG. 2 is a schematic lateral view of a lateral surface of the OLED display of FIG. 1.

Referring to FIG. 1 and FIG. 2, the OLED display according to an exemplary embodiment includes a display panel 100, an encapsulation substrate 300, a touch electrode layer 400, a polarization layer 310, a resin layer 320, and a window 900.

The OLED display according to an exemplary embodiment includes a driving IC 500 and a flexible printed circuit board (FPCB) 600 attached to a display substrate 110.

The OLED display includes a display area DA where images are displayed and a peripheral area PA formed at the periphery of and surrounding the display area DA when viewed from a top plane view.

The display panel 100 includes the display substrate 110, a thin film display layer 200, a shielding electrode 220, and an insulating layer 240.

The display substrate 110 is formed of an electrically insulating material such as transparent glass or plastic. The thin film display layer 200, the shielding electrode 220, and the insulating layer 240 are sequentially formed on the display substrate 110.

The thin film display layer 200 includes a plurality of pixels and each pixel includes a switching thin film transistor Qs, a driving thin film transistor Qd, a storage capacitor Cst, and a plurality of OLEDs LD. The pixels are formed in the display area DA of the thin film display layer 200.

The encapsulation substrate 300 is formed on the display panel 100 and the touch electrode layer 400 is arranged to face the thin film display layer 200 while being placed under the encapsulation substrate 300.

The touch electrode layer 400 can sense touch input when an object approaches or touches the touch electrode layer 400. Here, contact generally refers to not only when an external object such as a user's finger directly touches the touch electrode layer 400, but also to when the external object approaches the touch electrode layer 400 or hovers over the touch electrode layer 400.

The display driving IC 500 applies a display driving signal to the thin film display layer 200. The touch driving IC 500 receives and outputs a touch driving signal to the touch electrode layer 400 and is formed at one side of the peripheral area PA of the display substrate 110. As illustrated in FIGS. 1 and 2, the display driving IC and the touch driving IC are integrated into a single IC 500, but when necessary, they can be divided into separate ICs.

A seal member or sealing member 190 including metal conductive balls or conductive particles (not shown) therein can be formed in the peripheral area DA of the display substrate 110 and can contact the touch electrode layer 400.

In the embodiment of FIGS. 1 and 2, the touch electrode layer 400 is connected to the touch driving IC 500 through the metal conductive balls included in the seal member 190. The metal conductive balls may include gold (Au) or silver (Ag).

Also, the display driving IC 500 and the touch driving IC 500 are connected to the flexible printed circuit board (FPCB) 600 formed at one side of the peripheral area PA of the display substrate 110 through a connection 610.

In the embodiment of FIGS. 1 and 2, a controller 650 is formed on the flexible printed circuit board (FPCB) 600. The controller 650 generates the signals (i.e., the display driving signal and the touch driving signal) that are transmitted to the display driving IC 500 and the touch driving IC 500 and stores/analyses the signals received from the display driving IC 500 and the touch driving IC 500.

The shielding electrode 220 and the insulating layer 240 are interposed between the thin film display layer 200 and the touch electrode layer 400.

The shielding electrode 220 can reduce undesired interference between the thin film display layer 200 and the touch electrode layer 400 while being interposed between the thin film display layer 200 and the touch electrode layer 400.

In some embodiments, the touch electrode layer 400 is a capacitance type touch sensor including a plurality of touch electrodes. For example, the touch electrode layer 400 may be a capacitive touch screen coated with a transparent conductor such as ITO to form a plurality of touch electrodes. When a conductor such as a finger of a user is very close to the capacitive touch screen, a change in capacitance is generated in the touch electrodes that can be measured and used to determine the position of the touch input.

When the touch electrode layer 400 is integrated with the thin film display layer 200, the voltages applied to a plurality of pixels of the thin film display layer 200 may interfere with the capacitance detection signal, thereby causing erroneous touch position data since the thin film display layer 200 is very close to the touch electrode layer 400.

In the OLED display according to an exemplary embodiment, by forming the shielding electrode 220 between the thin film display layer 200 and the touch electrode layer 400, the interference of the undesired signals can be reduced between the thin film display layer 200 and the touch electrode layer 400.

In some embodiments, the shielding electrode 220 is connected to the touch driving IC 500 and the display driving IC 500. The touch driving IC 500 and the display driving IC 500 receive a voltage signal of a predetermined level through the controller 650 and the flexible printed circuit board (FPCB) 600.

Here, the touch control signal and the voltage signal of the predetermined level are generated by the controller 650 and are respectively applied to the touch electrode layer 400 and the shielding electrode 220.

In this embodiment, the voltage signal of the predetermined level applied to the shielding electrode 220 can be applied as a general voltage Vd or a ground voltage.

The shielding electrode 220 is formed of a transparent electrode. For example, the transparent electrode is formed of a material such as ITO, IZO, ITZO, or, ATO. This is enable transmission of images from the display area DA positioned thereunder.

The insulating layer 240 is formed on the shielding electrode 220.

The insulating layer 240 is formed between the shielding electrode 200 and the touch electrode layer 400, thereby electrically insulating the shielding electrode 200 from the touch electrode layer 400.

The insulating layer 240 may be formed of a single layer of a silicon nitride (SiNx) or a dual-layer structure in which a silicon nitride (SiNx) and a silicon oxide (SiOx) are deposited.

The polarization layer 310, the resin layer 320, and the window 900 are sequentially formed on the encapsulation substrate 300.

The polarization layer 310 reduces reflection of external light to increase the contrast ratio and the resin layer 320 is an adhesive layer to adhere the window 900 to the polarization layer 310. The resin layer 320 can be hardened via irradiation of ultraviolet rays. The window 900 protects the thin film display layer 200 and the touch electrode layer 400.

The window 900 is adhered to the polarization layer 310 by the resin layer 320 and the resin layer 320 is hardened by ultraviolet rays, thereby adhering the window 900 to prevent the window 900 from being detached.

The window 900 can be formed of one or more of the following materials: poly(methyl methacrylate) (PMMA), an acryl, and PET, and can be flexible.

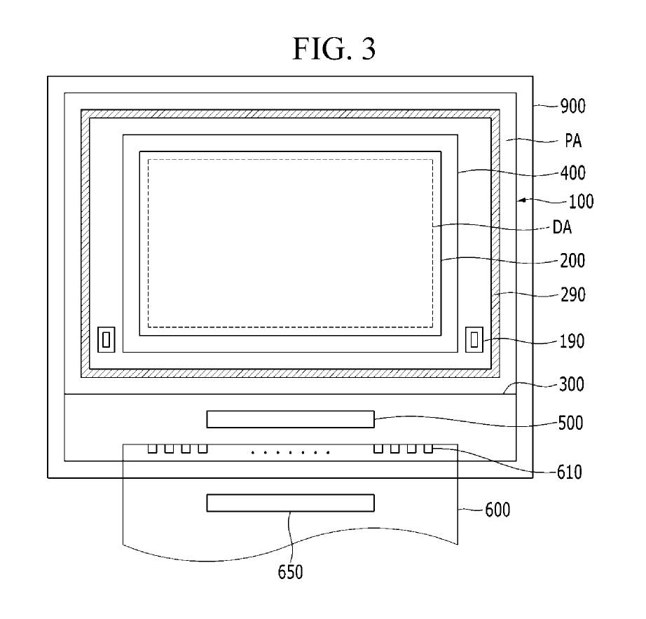

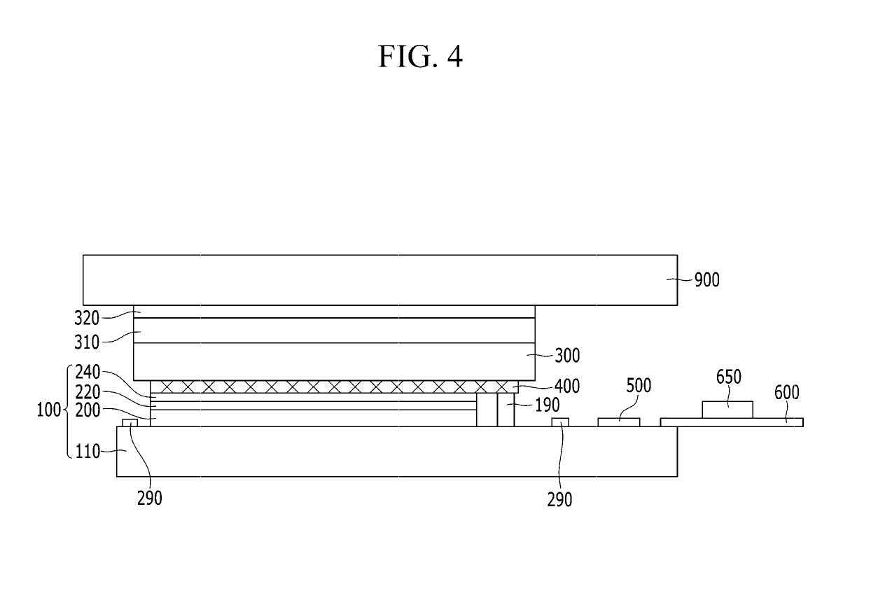

Next, an OLED display according to another exemplary embodiment will be described with reference to FIG. 3 and FIG. 4.

FIG. 3 is a schematic top plan view of an OLED display according to another exemplary embodiment. FIG. 4 is a schematic lateral view of a lateral surface of the OLED display of FIG. 3.

Referring to FIG. 3 and FIG. 4, the OLED display according to an exemplary embodiment includes the display panel 100, the encapsulation substrate 300, the touch electrode layer 400, the polarization layer 310, the resin layer 320, and the window 900. The display panel 100 includes the display substrate 110, the thin film display layer 200, the shielding electrode 220, and the insulating layer 240.

The OLED display according to the exemplary embodiment of FIGS. 3 and 4 also includes the driving IC 500 and the flexible printed circuit board (FPCB) 600 attached to the display substrate 110.

The OLED display includes a display area DA where an image is displayed and a peripheral area PA formed at the periphery of the display area DA when viewed in a top plane view.

The OLED display according to FIGS. 3 and 4 is substantially the same as the OLED display of FIG. 1 except for the inclusion of a guide ring 290. Hence, like constitutional elements have like reference numerals and no repeated descriptions of the like constitutional elements will be provided.

The guide ring 290 is formed near the edge of the peripheral area PA on the display substrate 110.

The guide ring 290 can remove the influence of external static electricity that flows into the display panel 100. For this, the guide ring 290 is connected to the touch driving IC 500 and the display driving IC 500. The touch driving IC 500 and the display driving IC 500 are applied with a voltage signal of a predetermined level through the controller 650 and the flexible printed circuit board (FPCB) 600. In this embodiment, the voltage signal of the predetermined level applied to the guide ring 290 is applied with as the general voltage Vd or the ground voltage.

That is, when external static electricity flows into the display panel 100, the external static electricity first flows through the guide ring 290 applied with the ground voltage such that the external static electricity can be prevented from being introduced into the display panel 100.

In some embodiments, the guide ring 290 is formed of the same material as the shielding electrode 220.

That is, the guide ring 290 may be formed of a material such as ITO, IZO, ITZO, or ATO which is used to form the transparent electrode material.

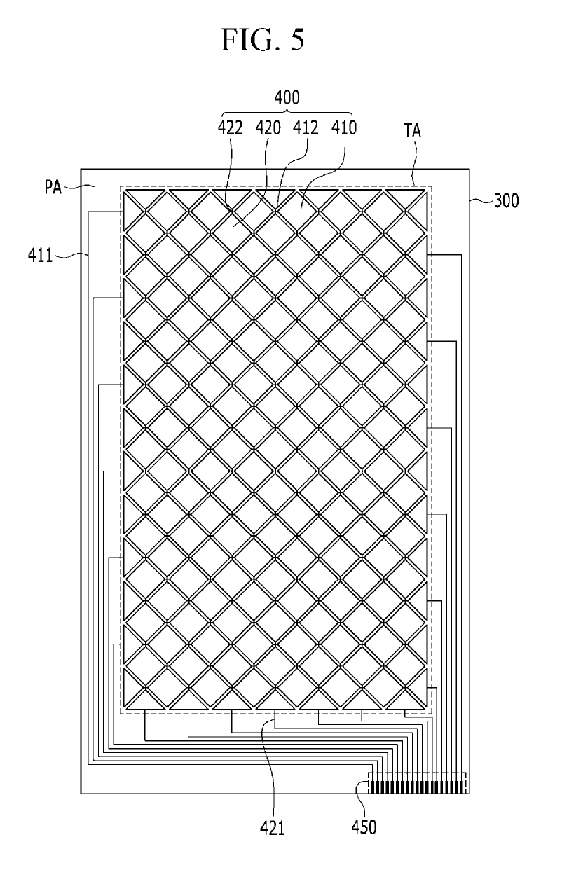

The touch electrode layer according to an exemplary embodiment will now be described with reference to FIG. 5 to FIG. 7.

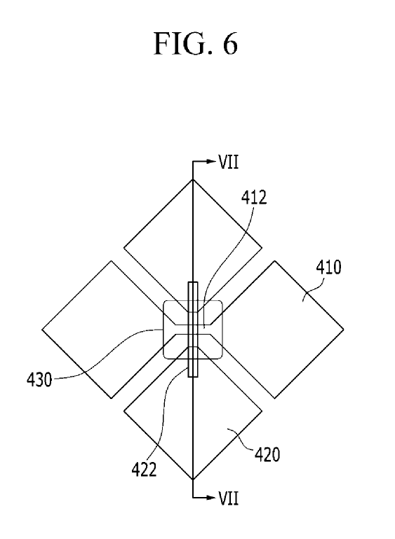

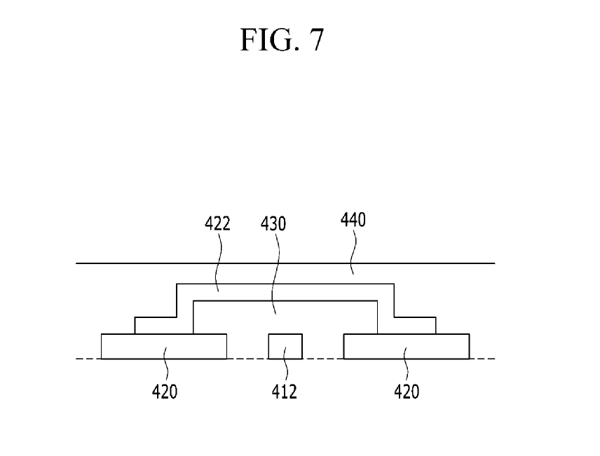

FIG. 5 is a top plan view of a touch electrode layer of the OLED display shown in FIG. 1 and FIG. 3. FIG. 6 is a partial enlarged view of the touch electrode layer shown in FIG. 5. FIG. 7 is a cross-sectional view taken along line VII-VII of FIG. 6.

Referring to FIG. 5, the touch electrode layer 400 is formed on the encapsulation substrate 300. The touch electrode layer 400 is formed in a touch active area TA where touch input can be sensed. The touch active area TA may be the entire display area DA and may also include a portion of the peripheral area. Further, in other embodiments, the touch active area TA overlaps only a portion of the display area DA.

The touch electrode layer 400 can sense touch input by various methods. For example, contact sensing can be classified into various types based on the sensing technology, such as a resistive type, a capacitive type, an electro-magnetic type (EM), and an optical type.

In the present exemplary embodiment, capacitive type contact sensing will be described as an example.

The touch electrode layer 400 includes a plurality of touch electrodes and the touch electrodes include a plurality of first touch electrodes 410 and a plurality of second touch electrodes 420. The first touch electrode 410 and the second touch electrode 420 are separated from each other.

The first touch electrodes 410 and the second touch electrodes 420 are alternately arranged so as to not substantially overlap each other in the touch active area TA. The first touch electrodes 410 may be arranged in one of a column direction and a row direction and the second touch electrodes 420 may also be arranged in one of a column direction and a row direction.

The first and second touch electrodes 410 and 420 are arranged on the same layer. However, the described technology is not limited thereto and the first and second touch electrodes 410 and 420 can be formed on different layers. The first and second touch electrodes 410 and 420 may each have a quadrangular shape, but are not limited thereto, and may have various shapes such as having protrusions to improve the sensitivity of the touch electrode layer 400.

The first touch electrodes 410 arranged in the same row or column are electrically connected to each other and are separated from each other inside or outside the touch active area TA. Similarly, at least a portion of the second touch electrodes 420 arranged in the same row or column are electrically connected to each other and are separated from each other inside or outside the touch active area TA. For example, as illustrated in FIG. 5, the first touch electrodes 410 are arranged in the same row and are electrically connected to each other inside the touch active area TA. Similarly, the second touch electrodes 420 are arranged in the same column and are electrically connected to each other inside the touch active area TA. In more detail, the first touch electrodes 410 positioned in each row are electrically connected to each other through a plurality of first connections 412 and the second touch electrodes 420 positioned in each column are electrically connected to each other through a plurality of second connections 422.

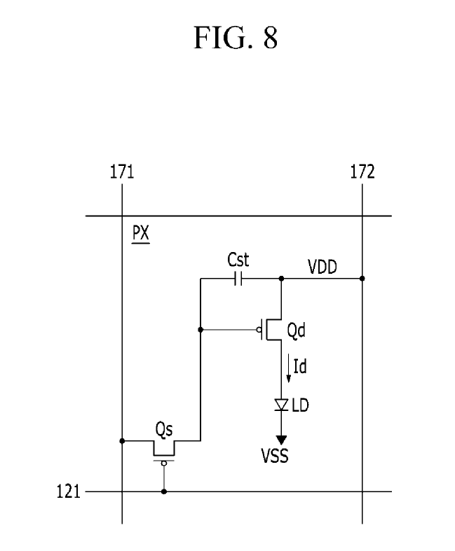

The first touch electrodes 410 connected to each other in each row are connected to the touch driving unit 550 through a plurality of first touch wirings 411 and the second touch electrodes 420 connected to each other in each column are connected to the touch driving unit 550 through a plurality of second touch wirings 421. The first and second touch wirings 411 and 421 can be positioned in the peripheral area PA as shown in FIG. 8 or they can be positioned in the touch active region TA. Ends of the first and second touch wirings 411 and 421 form a pad part or wiring pad 450 in the peripheral area PA of the encapsulation substrate 300.

The pad part 450 is connected to the touch driving IC 500 through the metal conductive balls included in the seal member 190.

Referring to FIG. 6 and FIG. 7, the first connection 412 connecting the adjacent first touch electrodes 410 is formed on the same layer as the first touch electrode 410 and is formed of the same material as the first touch electrode 410. That is, the first touch electrode 410 and the first connection 412 are integrally formed and can be simultaneously patterned.

The second connection 422 connecting the adjacent second touch electrodes 420 is formed on a different layer from the second touch electrode 420. That is, the second touch electrode 420 and the first connection 412 are separated from each other and can be separately patterned. The second touch electrode 420 and the second connection 422 are connected through direct contact.

A first insulating layer 430 is positioned between the first connection 412 and the second connection 422, thereby electrically insulating the first connection 412 and the second connection 422 from each other. The first insulating layer 430 may be formed as a plurality of independent island-shaped insulators arranged at every intersection between the first and second connections 412 and 422. The first insulating layer 430 exposes at least a portion of the second touch electrode 420 so that the second connection 422 can be electrically connected to the second touch electrode 420. The first insulating layer 430 may have rounded corners and may be formed of one or more of the following materials: silicon oxide (SiOx), silicone nitride (SiNx), and/or silicone oxynitride (SiOxNy).

A second insulating layer 440 is formed on the first touch electrode 410, the second touch electrode 420, and the second connection 422. The second insulating layer 440 is formed throughout the touch active area TA and may be formed of one or more of the following materials: silicon oxide (SiOx), silicone nitride (SiNx), and/or silicone oxynitride (SiOxNy).

In addition, in contrast to the embodiment illustrated in FIGS. 5 to 7, the second connection 422 connecting the second touch electrodes 420 adjacent to each other can be formed on the same layer as the first touch electrode 410 and integrated with the first touch electrode 410 and the first connection 412 connecting the first touch electrodes 410 adjacent to each other can be formed on a different layer from the first touch electrode 410.

The first and second touch electrodes 410 and 420 may have a predetermined transmittance or greater so that light emitted from the thin film display layer 200 can be transmitted therethrough. For example, the first and second touch electrodes 410 and 420 may be formed of a transparent conductive material, such as ITO, IZO, a thin metal layer such as a silver nanowire (AgNW), a metal mesh, and carbon nanotubes (CNT), but are not limited thereto. The materials of the first connection 412 and the second connection 422 are the same as the materials of the touch electrodes.

The first and second touch wirings 411 and 421 may include the transparent conductive material forming the first and second touch electrodes 410 and 420 or a low resistive material such as molybdenum (Mo), silver (Ag), titanium (Ti), copper (Cu), aluminum (Al), and molybdenum/aluminum/molybdenum (Mo/Al/Mo).

The first and second touch electrodes 410 and 420 adjacent to each other form a mutual sensing capacitor functioning as the touch sensor. The mutual sensing capacitor receives a sensing input signal through one of the first and second touch electrodes 410 and 420 and outputs a sensing output signal which reflects the change in the amount of stored charge due to contact of the external object through the other touch electrode.

In contrast to the embodiment illustrated in FIGS. 5 to 7, the first and second touch electrodes 410 and 420 can be separated from each other and can be connected to a touch sensor controller through touch wires (not illustrated). In this embodiment, each touch electrode forms a self-sensing capacitor as the touch sensor. The self-sensing capacitor receives the sensing input signal to be charged by a predetermined charge amount and the outputs a sensing output signal that is different from the sensing input signal due to a change in the stored amount of charge generated when the external object such as a finger makes contact.

Next, the thin film display layer according to the present exemplary embodiment will be described with reference to FIG. 8 to FIG. 10. As described above, the thin film display layer 200 includes the plurality of pixels.

FIG. 8 is an equivalent circuit diagram of one pixel of the OLED display shown in FIG. 1 and FIG. 3.

Referring to FIG. 8, the OLED display according to the present exemplary embodiment includes a plurality of signal lines 121, 171, and 172 and a plurality of pixels PX respectively connected to the signal lines and substantially arranged in a matrix.

The signal lines include a plurality of gate lines 121 transmitting a plurality of gate signals (or scan signals), a plurality of data lines 171 transmitting a plurality of data signals, and a plurality of driving voltage lines 172 transmitting a driving voltage ELVDD. The gate signals and data signals are received through the display driving IC 500.

The gate signal lines 121 extend substantially in a row direction and are substantially parallel to each other. The data lines 171 and the driving voltage lines 172 extend substantially in a column direction and substantially parallel to each other.

Each pixel PX includes a switching thin film transistor Qs, a driving thin film transistor Qd, a storage capacitor Cst, and an OLED LD.

The switching transistor Qs includes a control terminal, an input terminal, and an output terminal, in which the control terminal is connected to the scanning signal line 121, the input terminal is connected to the data line 171, and the output terminal is connected to the driving transistor Qd. The switching transistor Qs transmits the data signal received from the data line 171 to the driving transistor Qd in response to the scanning signal received from the scanning signal line 121.

The driving transistor Qd also includes a control terminal, an input terminal, and an output terminal, in which the control terminal is connected to the switching transistor Qs, the input terminal is connected to the driving voltage line 172, and the output terminal is connected to the OLED LD. The driving transistor Qd applies an output current ILD having a magnitude which varies according to the voltage applied between the control terminal and the output terminal thereof.

The capacitor Cst is connected between the control terminal and the input terminal of the driving transistor Qd. The capacitor Cst stores the data signal applied to the control terminal of the driving transistor Qd and maintains the stored data signal even after the switching transistor Qs is turned off.

The OLED LD has, for example, an anode connected to the output terminal of the driving transistor Qd and a cathode connected to a common voltage Vss. The OLED LD emits light having an intensity that is varied according to the output current Id of the driving transistor Qd, to display an image.

The illustrated switching transistor Qs and the driving transistor Qd are re-channel field effect transistors (FET); however, depending on the embodiment, at least one of the switching transistor Qs and the driving transistor Qd may be a p-channel FET. Moreover, the connection relationship among the transistors Qs and Qd, the storage capacitor Cst, and the OLED LD can be changed based on the implementation of the OLED display.

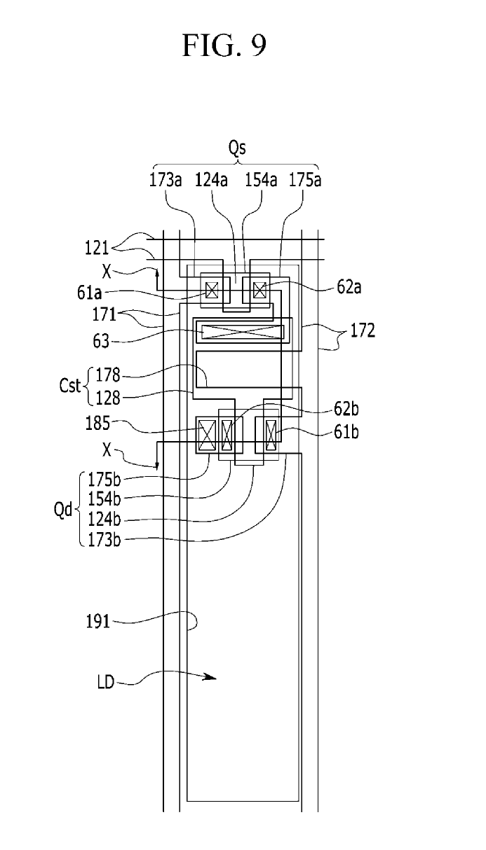

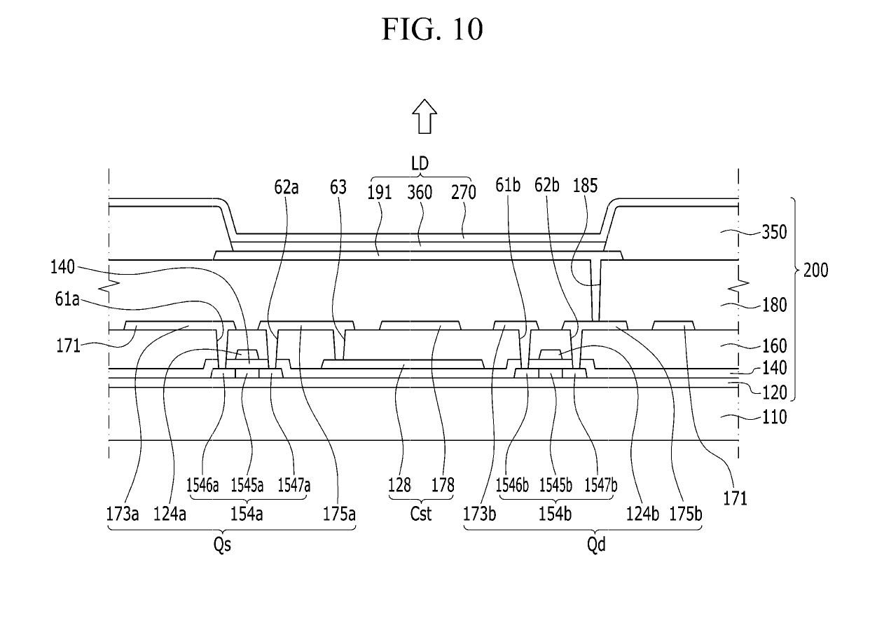

FIG. 9 is a layout view of one pixel of the OLED display shown in FIG. 1 and FIG. 3. FIG. 10 is a cross-sectional view taken along line X-X of FIG. 9.

Referring to FIG. 9 and FIG. 10, the thin film display layer 200 is formed on the display substrate 110 in the OLED display of FIG. 1 and FIG. 3.

The thin film display layer 200 includes a buffer layer 120, a switching semiconductor layer 154a, a driving semiconductor layer 154b, a gate insulating layer 140, gate lines 121, a first storage capacitor plate 128, an interlayer insulating layer 160, data lines 171, driving voltage lines 172, a switching drain electrode 175a, a driving drain electrode 175b, and a passivation layer 180.

The buffer layer 120 is formed on the display substrate 110 and may be formed as a single layer of a silicon nitride (SiNx) or as a double-layered structure in which a silicon nitride (SiNx) and a silicon oxide (SiOx) are laminated. The buffer layer 120 serves to planarize the surface of the display substrate 110 while preventing an unnecessary component such as an impurity or moisture from permeating therethrough.

The switching semiconductor layer 154a and the driving semiconductor layer 154b are provided to be separated from each other on the buffer layer 120. The switching semiconductor layer 154a and the driving semiconductor layer 154b are formed of polysilicon and include channel regions 1545a and 1545b, source regions 1546a and 1546b, and drain regions 1547a and 1547b. The source regions 1546a and 1546b and the drain regions 1547a and 1547b are respectively provided at both sides of the channel regions 1545a and 1545b.

The channel regions 1545a and 1545b are formed of polysilicon which is not doped with an impurity, that is, they are intrinsic semiconductors and the source regions 1546a and 1546b and the drain regions 1547a and 1547b are formed of polysilicon which is doped with an impurity, that is, they are doped semiconductors.

The gate insulating layer 140 is provided on the channel regions 1545a and 1545b of the switching and driving semiconductor layers 154a and 154b. The gate insulating layer 140 may be a single layer or a multilayer including at least one of a silicon nitride and a silicon oxide.

The gate lines 121 and the first storage capacitor plate 128 are formed on the gate insulating layer 140.

The gate lines 121 extend in a horizontal direction and transmit a gate signal and include a switching gate electrode 124a protruding toward the switching semiconductor layer 154a from the gate line 121.

The first storage capacitor plate 128 includes a driving gate electrode 124b protruding toward the driving semiconductor layer 154b from the first storage capacitor plate 128. The switching gate electrode 124a and the driving gate electrode 124b respectively overlap the channel regions 1545a and 1545b.

The interlayer insulating layer 160 is formed on the gate lines 121, the first storage capacitor plate 128, and the buffer layer 120.

A switching source contact hole 61 a and a switching drain contact hole 62a that respectively expose the source region 1546a and the drain area 1547a of the switching semiconductor layer 154a are formed in the interlayer insulating layer 160. In addition, a driving source contact hole 61b and a driving drain contact hole 62b that respectively expose the source region 1546b and the drain region 1547b of the driving semiconductor layer 154b are formed in the interlayer insulating layer 160.

The data lines 171, the driving voltage lines 172, the switching drain electrode 175a, and the driving drain electrode 175b are formed on the interlayer insulating layer 160.

The data lines 171 transmit a data signal and extend in a direction crossing the gate lines 121, and include a switching source electrode 173a protruding toward the semiconductor 154a from the data line 171.

The driving voltage lines 172 transmit a driving voltage, are separated from the data lines 171, and extend in the same direction as the data lines 171. The driving voltage lines 172 include a driving source electrode 173b protruding toward the driving semiconductor layer 154b from the driving voltage line 172 and a second storage capacitor plate 178 protruding from the driving voltage line 172 and overlapping the first storage capacitor plate 128. Here, the first storage capacitor plate 128 and the second storage capacitor plate 178 form the storage capacitor Cst using the interlayer insulating layer 160 as a dielectric material.

The switching drain electrode 175a faces the switching source electrode 173a and the driving drain electrode 175b faces the driving source electrode 173b.

The switching source electrode 173a and the switching drain electrode 175a are respectively connected with the source region 1546a and the drain region 1547a of the switching semiconductor layer 154a through the switching source contact hole 61a and the switching drain contact hole 62a. In addition, the switching drain electrode 175a is extended and thus electrically connected to the first storage capacitor plate 128 and the driving gate electrode 124b through a first contact hole 63 formed in the interlayer insulating layer 160.

The driving source electrode 173b and the driving drain electrode 175b are connected to the source region 1546b and the drain region 1547b of the driving semiconductor layer 154b through the driving source contact hole 61b and the driving drain contact hole 62b.

The switching semiconductor layer 154a, the switching gate electrode 124a, the switching source electrode 173a, and the switching drain electrode 175a form the switching thin film transistor Qs, and the driving semiconductor layer 154b, the driving gate electrode 124b, the driving source electrode 173b, and the driving drain electrode 175b form the driving thin film transistor Qd.

The passivation layer 180 is formed on the data lines 171, the driving voltage lines 172, the switching drain electrode 175a, and the driving drain electrode 175b.

A second contact hole 185 exposing the driving drain electrode 175b is formed in the passivation layer 180.

The OLED LD and a pixel defining layer 350 are formed on the passivation layer 180.

The OLED LD includes a pixel electrode 191, an organic emission layer 360, and a common electrode 270.

The pixel electrode 191 is formed on the passivation layer 180 and is electrically connected to the driving drain electrode 175b of the driving thin film transistor Qd through the second contact hole 185 formed in the interlayer insulating layer 160. Such a pixel electrode 191 becomes the anode of the OLED LD.

The pixel electrode 191 may be made of a transparent conductive material such as ITO, IZO, zinc oxide (ZnO), or indium oxide (In2O3), or a reflective metal such as lithium (Li), calcium (Ca), lithium fluoride/calcium (LiF/Ca), lithium fluoride/aluminum (LiF/Al), aluminum (Al), silver (Ag), magnesium (Mg), or gold (Au).

The pixel defining layer 350 is formed at an edge portion of the pixel electrode 191 and on the passivation layer 180.

The pixel defining layer 350 includes an opening exposing the pixel electrode 191. The pixel defining layer 350 may be formed of a resin such as a polyacrylate or a polyimide.

The organic emission layer 360 is formed on the pixel electrode 191 in the opening of the pixel defining layer 350. The organic emission layer 360 is formed of multilayers including one or more of a light emitting layer, a hole injection layer (HIL), a hole transporting layer (HTL), an electron transporting layer (ETL), and an electron injection layer (EIL). When the organic emission layer 360 includes all the layers, the hole injection layer (HIL) is formed on a pixel electrode which is an anode, and the hole transporting layer (HTL), the light emitting layer, the electron transporting layer (ETL), and the electron injection layer (EIL) are sequentially laminated thereon.

The organic emission layer 360 may include a red organic emission layer emitting red light, a green organic emission layer emitting green light, and/or a blue organic emission layer emitting blue light. The red organic emission layer, the green organic emission layer, and the blue organic emission layer are formed in a red pixel, a green pixel, and a blue pixel, respectively, thereby implementing a color image.

Further, the organic emission layer 360 may implement a color image by laminating the red organic emission layer, the green organic emission layer, and the blue organic emission layer together in each of the red pixel, the green pixel, and the blue pixel, and forming a red color filter, a green color filter, and a blue color filter for each pixel. As another example, white organic emission layers emitting white light may be formed in each of the red pixel, the green pixel, and the blue pixel, and a red color filter, a green color filter, and a blue color filter may be formed for each pixel, thereby implementing the color image. When implementing the color image by using the white organic emission layer and the color filters, a deposition mask for depositing the red organic emission layer, the green organic emission layer, and the blue organic emission layer on respective pixels, that is, the red pixel, the green pixel, and the blue pixel, does not need to be used.

The white organic emission layer described in another example can be formed by one organic emission layer and includes a configuration formed so as to emit white light by laminating a plurality of organic emission layers. For example, the white organic emission layer may include a configuration which may emit white light by combining at least one yellow organic emission layer and at least one blue organic emission layer, a configuration which may emit white light by combining at least one cyan organic emission layer and at least one red organic emission layer, a configuration which may emit white light by combining at least one magenta organic emission layer and at least one green organic emission layer, or the like.

The common electrode 270 is formed on the pixel defining layer 350 and the organic emission layer 360. The common electrode 270 may be formed of a transparent conductive material such as ITO, IZO, ZnO, or In 203, or a reflective metal such as lithium (Li), calcium (Ca), lithium fluoride/calcium (LiF/Ca), lithium fluoride/aluminum (LiF/Al), aluminum (Al), silver (Ag), magnesium (Mg), or gold (Au). Such a common electrode 270 becomes the cathode of the OLED LD.

While the inventive technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light-emitting diode (OLED) display, comprising:
a display substrate including a display area configured to display an image and a peripheral area surrounding the display area;
a thin film display layer formed over the display substrate in the display area;
a shielding electrode formed over the entire surface of the thin film display layer;
an encapsulation substrate formed over the display substrate; and
a touch electrode layer interposed between the encapsulation substrate and the thin film display layer.

2. The OLED display of claim 1, further comprising an insulating layer interposed between the shielding electrode and the touch electrode layer.

3. The OLED display of claim 1, wherein the shielding electrode is transparent.

4. The OLED display of claim 3, wherein the shielding electrode is formed of one of the following materials: indium tin oxide (ITO), indium zinc oxide (IZO), indium tin zinc oxide (ITZO), and antimony tin oxide (ATO).

5. The OLED display of claim 1, further comprising:
a touch driving integrated circuit (IC) formed at one side of the peripheral area of the display substrate and configured to transmit a first signal to the touch electrode layer; and
a display driving IC configured to transmit a second signal to the thin film display layer.

6. The OLED display of claim 5, wherein the touch driving IC and the display driving IC are electrically connected to the shielding electrode.

7. The OLED display of claim 6, further comprising:
a flexible printed circuit board (FPCB) arranged at the one side of the peripheral area of the display substrate and electrically connected to the touch driving IC and the display driving IC; and
a controller electrically connected to the FPCB and configured to: i) generate the first and second signals, ii) respectively transmit the first and second signals to the touch driving IC and the display driving IC, and iii) generate a voltage signal having a predetermined level.

8. The OLED display of claim 7, wherein the controller is further configured to apply the voltage signal to the shielding electrode.

9. The OLED display of claim 8, wherein the voltage signal comprises a general voltage or a ground voltage.

10. The OLED display of claim 1, further comprising a guide ring formed over the display substrate in the peripheral area and configured to prevent static electricity from flowing into the display area.

11. The OLED display of claim 10, wherein the guide ring and the shielding electrode are formed of the same material.

12. The OLED display of claim 1, further comprising:
a polarization layer formed over the encapsulation substrate; and
a window formed over the polarization layer.

13. The OLED display of claim 12, further comprising a resin layer interposed between the polarization layer and the window.
